(19) United States
(12) Patent Application Publication
(10) Pub. No.: US 2023/0194997 A1
(43) Pub. Date: Jun. 22, 2023

(54) INCREASING OVERLAY MARGINS FOR LINES THAT SPAN RETICLE BOUNDARIES IN DIE-TO-DIE RETICLE STITCHING

(71) Applicant: Intel Corporation, Santa Clara, CA (US)

(72) Inventors: Mark Phillips, Hillsboro, OR (US); Shakul Tandon, Portland, OR (US)

(73) Assignee: Intel Corporation, Santa Clara, CA (US)

(21) Appl. No.: 17/558,417

(22) Filed: Dec. 21, 2021

(51) Int. Cl. G03F 7/20

(52) U.S. Cl. CPC G03F 7/70633; G03F 7/70475; G03F 7/70741; G03F 7/70466

(57) ABSTRACT

Reticles, line feature patterns, and methods are described related to improving overlay margins in reticle stitching applications. A first reticle to expose a first field includes a first portion of a line feature. The first portion has a pattern inclusive of one or more pattern features. The first reticle or a second reticle to expose a second field adjacent the first filed includes a second portion of the line feature. The second portion has an inverse pattern relative to the first pattern such that, when the first and inverse patterns are overlaid, a continuous merged region is formed.

### BACKGROUND

As the integrated circuit industry continues to produce ever more advanced devices for use in various electronic products such as computers, servers, and portable products inclusive of portable computers, electronic tablets, cellular phones, digital cameras, and the like, current die sizes are limited by the size of a standard lithographic reticle that results in one patterned field on the wafer. With ever increasing computational needs, there is a desire to fabricate dies that include multiple lithographic fields of a wafer. That is, in standard processing, the features of a die are fabricated using a single lithographic field that corresponds to a single lithographic exposure using a single reticle. However, there is an increasing desire to fabricate dies that include multiple (e.g., two or more) adjacent lithographic fields. Such fields may be exposed using different reticles or the same reticle. In either context, there is a desire to interconnect features of such fields. For example, metal lines that extend between adjacent fields are needed for interconnection, routing, etc. The interconnection of such features is achieved through reticle stitching (or exposure stitching), where features from adjacent fields/reticles are adjoined or stitched together to provide, after exposure and other fabrication processing, features that extend across the boundary between adjacent fields on the wafer.

However, such reticle stitching processing faces difficulties due to known lithographic limitations inclusive of placement error (registration error), distortion, and others. Such patterning problems can cause thin, high resistance metal lines or even disconnects. It is with respect to these and other considerations that the present improvements have been needed. Such improvements may become critical as the need to provide larger dies having more complicated features using reticle stitching is necessary to support ever more sophisticated electronics systems and complexes.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A illustrates an example monolithic die including line features fabricated by reticle stitching using overlapping line end features;

FIG. 1B illustrates another example monolithic die including line features fabricated by reticle stitching using overlapping line end features;

FIG. 2 illustrates an example lithographic patterning context for deploying reticle stitching using overlapping line end features;

FIG. 3A illustrates an example line feature generated by overlaying first and second portions deploying line end features having stair-step patterns;

FIG. 3B illustrates example portions of the example line feature of FIG. 3A showing segmented features thereof;

FIG. 3C illustrates additional characteristics of an example portion of the example line feature of FIG. 3A from a first reticle pattern and corresponding exposure;

FIG. 3D illustrates additional characteristics of example portion of the example line feature of FIG. 3A from a second exposure and the first reticle pattern or a second reticle pattern;

FIG. 3E illustrates the example line feature of FIG. 3A with misalignment between the portions thereof causing a gap between the portions;

FIG. 3F illustrates the example line feature of FIG. 3A with misalignment between the portions thereof causing an overlap between the portions;

FIG. 4A illustrates an example line feature generated by overlaying first and second portions deploying interlocking line end features;

FIG. 4B illustrates example portions of the example line feature of FIG. 4A showing segmented features thereof;

FIG. 5A illustrates an example line feature generated by overlaying first and second portions deploying notch and tab line end features;

FIG. 5B illustrates example portions of the example line feature of FIG. 5A showing segmented features thereof;

FIG. 6A illustrates an example line feature generated by overlaying first and second portions deploying grid based line end features;

FIG. 6B illustrates example portions of the example line feature of FIG. 6A showing segmented features thereof;

FIG. 7A illustrates an example line feature generated by overlaying first and second portions deploying parallel linear end features;

FIG. 7B illustrates example portions of the example line feature of FIG. 7A showing segmented features thereof;

FIG. 8A illustrates an example line feature generated by overlaying first and second portions deploying orthogonal linear end features;

FIG. 8B illustrates example portions of the example line feature of FIG. 8A showing segmented features thereof;

FIG. 9 is a flow diagram illustrating an example process for fabricating an integrated circuit device;

FIGS. 10A, 10B, 10C, 10D, and 10E are views of example integrated circuit device structures as particular fabrication operations are performed;

FIG. 11 is an illustrative diagram of a mobile computing platform employing a monolithic base die having layers selectively fabricated using reticle stitching; and

FIG. 12 is a functional block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. Herein, the term “completely” indicates not less than 95%, in recognition that absolutes are typically not expected or attainable in patterning contexts. For example, overlaid patterns that substantially fill a region cover not less than 90% of the region while overlaid patterns that completely fill a region cover not less than 95% of the region. Perfectly overlaid patterns fill 99-100% of a merged region. As used herein, the terms “monolithic”, “monolithically integrated”, and similar terms indicate the components of the monolithic overall structure form an indivisible whole not reasonably capable of being separated.

Reticle features, techniques, and devices are described herein related to improving overlay margins for lines that span reticle boundaries in reticle stitching applications.

As discussed, there is an increasing need to fabricate dies that include multiple (e.g., two or more) adjacent lithographic fields. Such techniques are characterized as die-to-die reticle stitching or exposure stitching. In such contexts, there are difficulties due to lithographic limitations including registration error, distortion, and others. The techniques and features discussed herein increase overlay, registration, and distortion margins for fabricating lines (e.g., metal lines) that span boundaries between reticles in die-to-die reticle stitching or exposure stitching contexts. The features discussed herein provide lines that are more robust to misregistration between adjacent stitched reticle fields. In some embodiments, the features include line end designs at the edges of reticles that overlap each other to create a crossover that is more robust to overlay, registration, and distortion errors between stitched reticle fields. Such features and techniques provide a design that results in less critical dimension (CD) variation and fewer failures, thereby increasing fab yields. Such features and techniques also prevent significant thinning (i.e., laterally in a top down view) of the metal signal lines at the interface, resulting in improved resistance characteristics of the signal lines (i.e., avoidance of higher resistance due to thinning).

Notably, creating features using lithography involves coating a wafer with a photosensitive resist, which is typically sensitive to light of a certain wavelength. The light of this wavelength is then shone through a mask that contains the desired pattern to be transferred to the wafer. Herein, patterns, regions, features and the like are discussed with respect to reticle mask patterns and resultant patterns on the photoresist interchangeably. It is noted that the pattern at the resist level is typically reduced (e.g., by 4×) from the reticle mask level and is invariably an imperfect reproduction. Herein, the discussed patterns, regions, or features may be at the reticle level (i.e., in the reticle mask) or at the resist level (e.g., either pre- or post-development). The region on the wafer that is exposed to the light generates photoacids that break down the resist polymer making it soluble in a developer solution. In reticle stitching contexts, a feature such as a line feature is generated by two different masks (or different regions of the same mask) exposed sequentially such that a portion of the line feature from the first exposure and a portion of the line feature from the second exposure are adjoined at the stitch. As used herein, the term adjoin indicates two features, portions, or regions are in contact with one another.

Since each exposure has a certain placement error and/or distortion error, the combined placement error and/or distortion error of the two exposures can result in a gap, an overlap, or both in the overlapping exposure regions, as discussed further herein below. Notably, absent the overlapping line end designs discussed herein (e.g., butting two line portions together), the gap or overlap causes a depletion of photoacids generated or an excess of photoacids generated, respectively. Depletion in photoacids can result in a decrease in CD or, in extreme cases, resist bridging or resist scum. An excess of photoacids can cause an undesirable CD bulge. The line end designs disclosed herein eliminate or minimize variations in photoacid concentrations due to registration mismatch and/or distortion error between the two exposures. For example, the discussed interface designs provide desirable perturbations in the concentration of the generated photoacid concentrations that are spread out over a larger interface area to minimize the variations in the regions of overlap of the resultant stitched line features even when a registration mismatch and/or distortion errors are present.

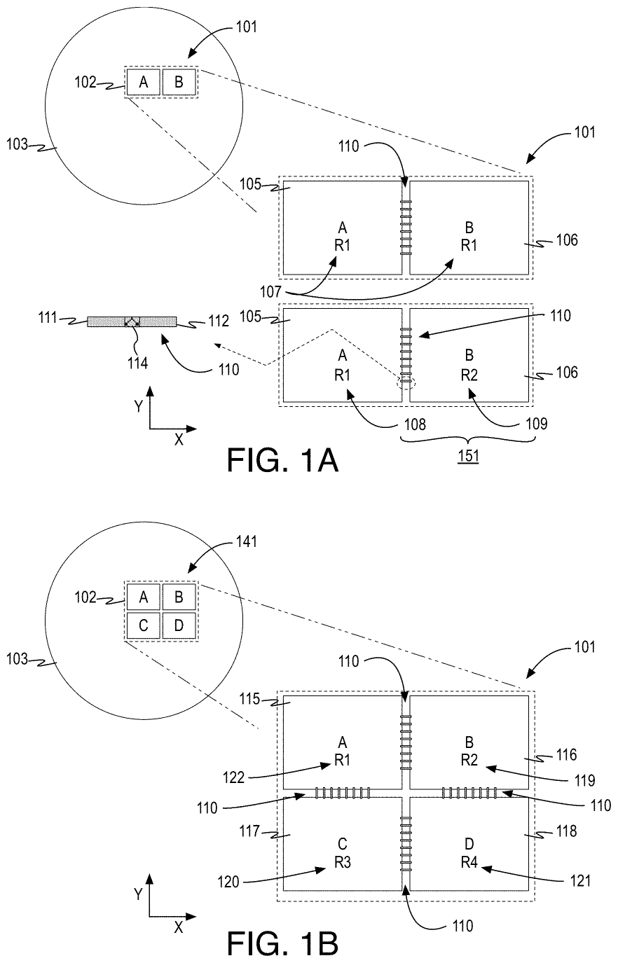

FIG. 1A illustrates an example monolithic die 101 including line features fabricated by reticle stitching using overlapping line end features, arranged in accordance with at least some implementations of the present disclosure. As shown, die 101 may be singulated from substrate wafer 103 using scribe cuts 102 that surround die 101 but do not intersect between fields 105, 106 (also labeled as A and B) of die 101 such that fields 105, 106 correspond to areas or regions patterned using separate lithography exposures. Fields 105, 106 may also be characterized as regions or tiles. Fields 105, 106 are patterned in separate lithography exposures that may include reticle stitched features or lines 110 (e.g., line features or metal signal lines) that are to be connected across fields 105, 106. As used herein, the term reticle stitched feature or line indicates a feature or line that crosses over between reticles and exposure fields such that one portion or region is from a first reticle and exposure field and a second portion or regions from a second reticle and exposure field.

A portion of each of lines 110 includes a continuous portion or region 111 from exposure of field 105 and a continuous portion or region 112 from exposure of field 106. The terms portion and region are used interchangeably herein. The term continuous with respect to a region or portion indicates the region or portion is uninterrupted. A continuous region having a width across a particular length indicates the region is uninterrupted in the area defined by the width and length. As shown, each of lines 110 includes a merged portion or region 114 that is defined by both exposure of field 105 and exposure of field 106, but not by either of the exposures independently. As used herein, the term merged portion or region indicates a resultant region of the overlay of patterns of two regions. As discussed, two overlaid patterns that substantially fill merged region 114 cover not less than 90% of the region and two overlaid patterns that completely fill a region cover not less than 95% of the region.

End line region patterns used to provide merged region 114 in a robust manner are discussed further herein. Such end line region patterns are provided in reticle patterns and transferred to a photoresist layer on or over substrate wafer 103. Such overlapping end line regions may be patterned using different reticles for each of fields 105, 106 or the same reticle for both of fields 105, 106. In examples where the same reticle is used, a same reticle 107 (R1) is used to pattern both fields 105, 106. In such examples, region 111 and the pattern of merged region 114 from the exposure of field 105 is at a first edge of reticle 107 (e.g., to pattern a right side of field 105) and region 112 and the pattern of merged region 114 from the exposure of field 106 is at an opposite edge of reticle 107 (e.g., to pattern a left side of field 105).

In examples where different reticles are used, the same relationship of the features is provided using different reticles 108 (R1), 109 (R2). For example, region 111 and the pattern of merged region 114 from the exposure of field 105 is at a first edge of reticle 108 (e.g., to pattern a right side of field 105) and region 112 and the pattern of merged region 114 from the exposure of field 106 is at an opposite edge of reticle 109 (e.g., to pattern a left side of field 105). As shown, reticles 108, 109 may be part of a reticle set 151 that are used to pattern dies 101. Such multi-reticle applications provide greater flexibility in patterning the features of dies 101.

FIG. 1B illustrates another example monolithic die 141 including line features fabricated by reticle stitching using overlapping line end features, arranged in accordance with at least some implementations of the present disclosure. As shown in FIG. 1B, lines 110 may be fabricated across reticle boundaries between any number of reticles and corresponding fields 115, 116, 117, 118. For example, using reticle stitching techniques, fields 115, 116, 117, 118 may scale to stitch an entire wafer or large portions (e.g., a half, a third, or a quarter) of a wafer. In the example of FIG. 1B, four reticles 122 (R1), 119 (R2), 120 (R3), 121 (R4), are deployed but any number may be used. Furthermore, FIG. 1B illustrates lines 110 may extend in any direction between fields 115, 116, 117, 118.

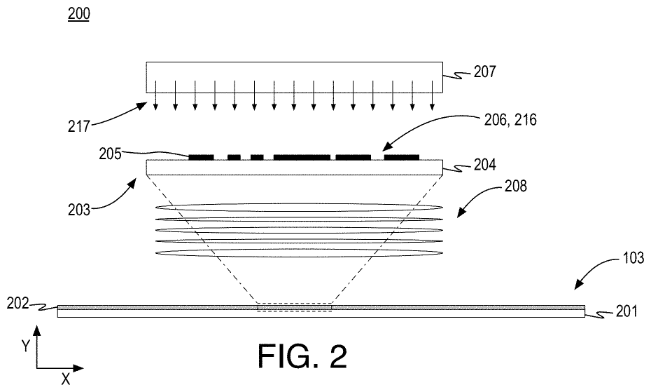

FIG. 2 illustrates an example lithographic patterning context 200 for deploying reticle stitching using overlapping line end features, arranged in accordance with at least some implementations of the present disclosure. In FIG. 2, a light source 207 is used to provide an exposure 217 through a reticle 203. Reticle 203 includes a transparent substrate 204 and a substantially opaque mask 205 providing a pattern 206 or 216 in a transparent substrate 204. For example, depending on the reticle 203 being deployed any pattern 206, 216, etc. discussed herein may be used.

Exposure 217 continues from reticle 203 through optics 208 to expose a photoresist layer 202 on or over a substrate 201 (e.g., a substrate wafer). As discussed, the resultant exposure generates photoacids that break down the resist polymer of photoresist layer 202, rendering it soluble in a developer solution. As discussed, pattern 206 or 216 is transferred from reticle 203 to photoresist layer 202. The pattern features, regions, etc. discussed herein are applicable to either or both of pattern 206 or 216 of reticle 203 and the resultant pattern of photoresist layer 202. Although illustrated with respect to the pattern being in transparent substrate 204 for use in positive photoresist applications, the pattern may be deployed in negative photoresist contexts.

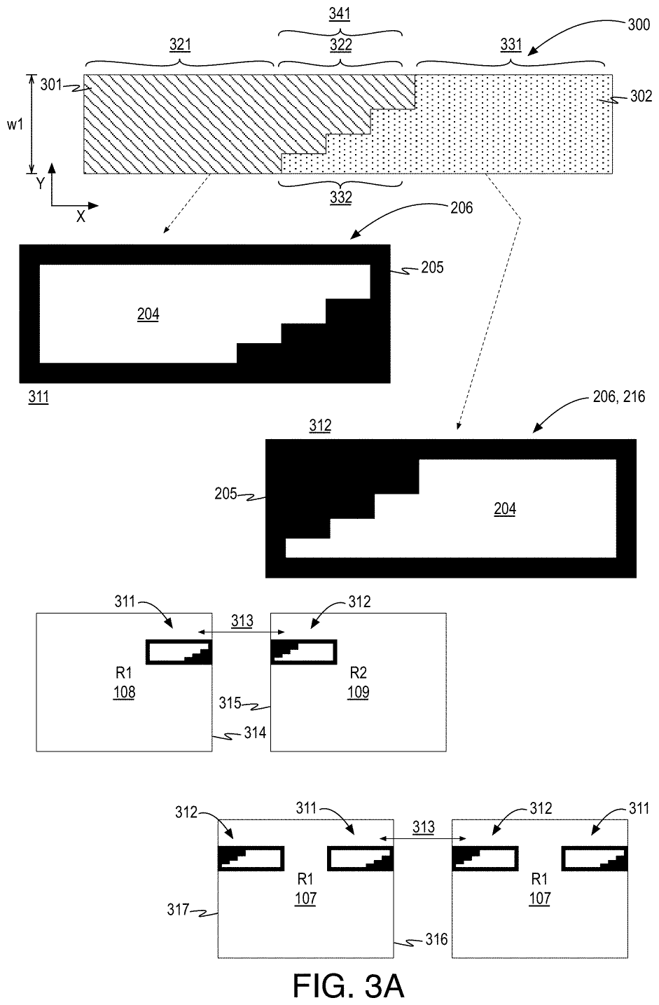

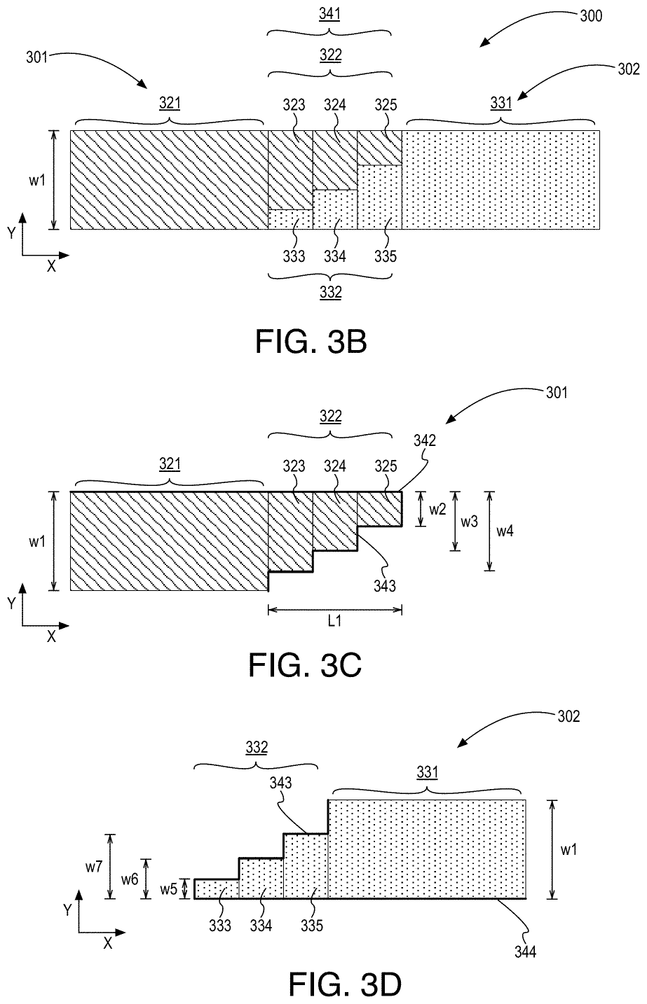

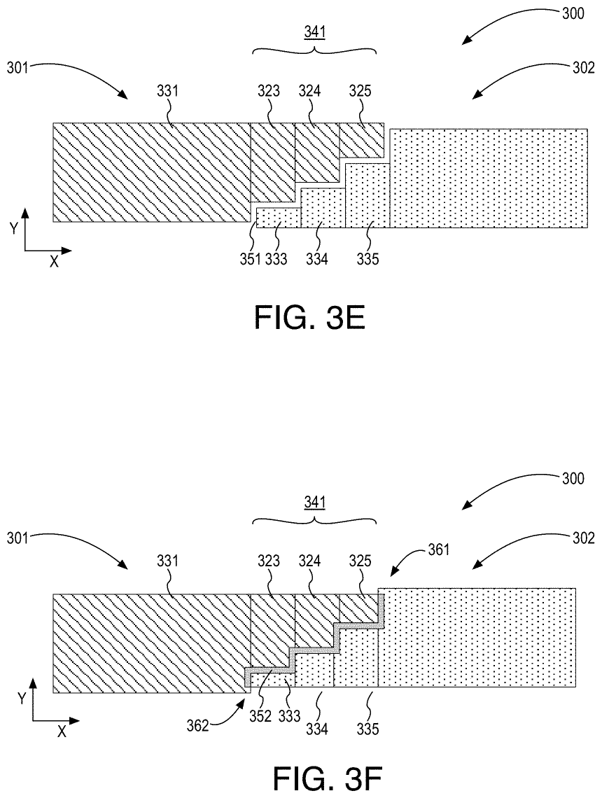

FIG. 3A illustrates an example line feature 300 generated by overlaying first and second portions 301, 302 deploying line end features having stair-step patterns, arranged in accordance with at least some implementations of the present disclosure. As shown in FIG. 3A, line feature 300 is fabricated by merging a first portion 301 from a first reticle and corresponding exposure and a second portion 302 from a second exposure using the first reticle or a second reticle. First portion 301 includes a first continuous feature or region 321 that has a width w1 along a length (in the x-dimension) thereof. As used herein, the term width provides a dimension taken across a line feature such that a length of the line feature extends in a long dimension and the width is orthogonal to the long dimension. Herein, line features are typically illustrated extending along a length in the x-dimension such that widths are commonly taken in the y-dimension. Although illustrated as straight lines, such lines may have jogs, changes in direction, etc. particularly moving away from the merged region. At the wafer level, line feature 300 (and other line features discussed herein) may be at any level of a back end of line (BEOL) metallization stack. In some embodiments, line feature 300 (and other line features discussed herein) are deployed at metal 7 (M7) and/or higher. In some embodiments, line feature 300 (and other line features discussed herein) are at lower metallization levels such as M4, M5, M6 and higher.

As shown, continuous region 321 is an uninterrupted region in an area defined by width w1 and the length of continuous region 321, which may extend in the x-dimension. Adjoining continuous region 321 is a region 322 of first portion 301. As shown, region 322 of first portion 301 has a stair-step pattern such that widths of features of region 322 decrease moving away from region 321, as discussed further herein below.

Similarly, second portion 302 of line feature 300 includes a first continuous feature or region 331 that has a width w1 along a length (in the x-dimension) thereof. Continuous region 331 is an uninterrupted region in an area defined by width w1 and the length of continuous region 321 and is adjoined by a region 322 of second portion 302. As shown, region 332 of second portion 302 has an inverse stair-step pattern relative to the stair-step pattern of region 322 such that widths of features of region 332 decrease moving away from region 331. Furthermore, the pattern of region 332 is the inverse of the pattern of region 322 such that they merge to form a merged region 341 that, when overlapped, is continuous and has no overlay regions. As used herein, the term inverse patterns indicates a pattern that is the opposite or complementary such that, when overlaid, the inverse fills in the corresponding pattern to provide a continuous pattern having no overlay.

As shown in FIG. 3A, portion 301 may be implemented in pattern 206 as pattern portion 311 such that pattern 206 is formed in transparent substrate 204 as surrounded by portions of opaque mask 205. Similarly, portion 302 may be implemented in pattern 206 or pattern 216 as pattern portion 312 such that pattern 206 or pattern 216 is also formed in transparent substrate 204 as surrounded by portions of opaque mask 205. As discussed, such pattern portions 311 may be provided in the same reticle or in different reticles.

In contexts where different reticles 108, 109 are deployed, as shown, pattern portion 311 is provided adjacent to and orthogonal to an edge 314 of reticle 108 such as at the right edge in the illustrated example. Pattern portion 312 is then provided at an opposite edge 315 (e.g., adjacent to and orthogonal to edge 315) of reticle 109 such as at the left edge as illustrated. Although illustrated with respect to right and left edges 314, 315, top and bottom opposing edges may also be used. It is noted that, in exposure, an overlap 313 of edge 314 and edge 315 is then deployed to provide merged region 341 during processing.

In contexts where the same reticle 107 is used, pattern portion 311 is provided adjacent to and orthogonal to an edge 316 of reticle 107 such as at the right edge in the illustrated example and pattern portion 312 is provided at an opposite edge 317 (e.g., adjacent to and orthogonal to edge 317) of reticle 107 such as the left edge (although top and bottom edges may be used). Notably, pattern portions 311, 312 must be provided on the opposite edges of the same reticle for adjacent fields to see suitable patterns for overlap 313 to provide a resultant line feature 300. Although illustrated with respect to portions of line feature 300, any portions or patterns discussed herein may be deployed on different reticles 108, 109 or the same reticle 107.

FIG. 3B illustrates example portions 301, 302 of example line feature 300 showing segmented features thereof, arranged in accordance with at least some implementations of the present disclosure. In FIG. 3B, portion 301 is illustrated as segmented into rectangular region 321 and rectangular features 323, 324, 325. Likewise, portion 302 is illustrated as segmented into rectangular region 331 and rectangular features 333, 334, 335. Such segmentation is provided for the sake of clarity of presentation. Notably, reticle patterns or features may be formed using any lines or shapes inclusive of diagonal or curved lines and the techniques discussed herein may be deployed in such contexts. However, due to simplicity in manufacturing, the size of features, and other constraints Manhattan routing or patterning is typically deployed.

As discussed, portions 301, 302 have interlocking stair-step patterns such that, for portion 301, feature 323 adjoins region 321, feature 324 adjoins feature 323, and feature 325 adjoins feature 324 and the width of such features decreases moving away from region 321. Similarly, for portion 302, feature 335 adjoins region 331, feature 334 adjoins feature 335, and feature 333 adjoins feature 334 with the width of such features decreases moving away from region 331. Also as shown, across portions 301, each of corresponding features 323, 333, corresponding features 324, 334, and corresponding features 325, 335 sum to a total width w1 that is shared with regions 321, 331. Thereby, line feature 300 has a constant width along a length thereof. For example, a constant width across line feature 300 advantageously provides predictable line resistance, consistent design constraints, and other advantages across field boundaries. Notably, features 323, 324, 325 provide a pattern in region 322 that is the inverse of the pattern in region 332 provided by features 333, 334, 335 such that, when overlaid, the patterns provide merged region 341 that is continuous and absent shared overlay regions. As used herein, the term shared overlay region indicates a region that is covered by both portion 301, 302 (i.e., covered by two reticle patterns and/or exposures).

FIG. 3C illustrates additional characteristics of example portion 301 of line feature 300 from a first reticle pattern and corresponding exposure, arranged in accordance with at least some implementations of the present disclosure. As shown in FIG. 3C, features 323, 324, 325 have a shared edge 342 with region 321. Although illustrated with shared edge 342, other patterns may be used. As used herein, the term shared edge indicates a linear continuous edge extending across features sharing the edge. Furthermore, feature 323 has a width w4, feature 324 has a width w3, and feature 325 has a width w5, such that w4 is greater than w3 and w3 is greater than w2. In the illustrated example, each of features 323, 324, 325 has the same length L1/3. Although illustrated with such characteristics, other features may be used. For example, one, two, four, five, or more features may be used and the features may have differing lengths. Furthermore, a constant step down in widths may not be deployed.

Also shown in FIG. 3C, region 322, and therefore merged region 341, may have a length L1. The width w1 of line feature 300 may be any suitable width attainable by the lithographic process being applied. For example, width w1 may be in the range of 200 to 300 nm, in the range of 150 to 200 nm, in the range of 100 to 150 nm or less. Length L1 may also be any suitable length with greater lengths providing greater overlap and dispersion of photoacids at the cost of wasting space and smaller lengths having the opposite effect. In some embodiments, the ratio of length L1 to width w1 (e.g., L1/w1) is about 1. In some embodiments, the ratio of length L1 to width w1 is in the range of 0.5 to 0.8. In some embodiments, the ratio of length L1 to width w1 is in the range of 0.8 to 1.2. In some embodiments, the ratio of length L1 to width w1 is in the range of 1.1 to 1.5. In some embodiments, the ratio of length L1 to width w1 is in the range of 1.5 to 2. Other ratios may be used. It is noted that the line end features in region 322 may be evident, without corresponding region 332 at regions of a substrate wafer where no stitching occurs, such as at an edge of wafer substrate 103.

Furthermore, FIG. 3C illustrates a shared boundary 343 between portion 301 and portion 302 within merged region 341. The techniques discussed herein advantageously increase the shared boundary length between portion 301 and portion 302 to provide much smaller variations in photoacid concentrations when misalignment or distortion occurs. As used herein, the term shared boundary length indicates a length of shared boundary between two regions, which, in the examples herein, is typically a Manhattan distance (i.e., the total of the x- and y-dimensions of the shared boundary or boundaries). For example, in contrast to butting line portions, where the shared boundary length is w1, the end line features described herein create a shared boundary length that is greater than width w1. In some embodiments, the shared boundary length is not less than 1.5 times width w1. In some embodiments, the shared boundary length is not less than 1.75 times width w1. In some embodiments, the shared boundary length is not less than twice width w1. In some embodiments, the shared boundary length is not less than three times width w1. In some embodiments, the shared boundary length is not less than five times width w1. Other multiples may be used. Such a meandering boundary greatly reduces the variation of photoacid concentration in the area of merged region 341.

FIG. 3D illustrates additional characteristics of example portion 302 of line feature 300 from a second exposure and the first reticle pattern or a second reticle pattern, arranged in accordance with at least some implementations of the present disclosure. As discussed above, the line end feature of portion 302 has an inverse pattern with respect to that of portion 301. As shown in FIG. 3D, features 335, 334, 335 have a shared edge 344 with region 331. Furthermore, feature 333 has a width w5, feature 334 has a width w6, and feature 335 has a width w7, such that w7 is greater than w6 and w6 is greater than w5. Notably, corresponding features with respect to portion 301 sum to width w1 such that the sum of w5 and w4 is w1, the sum of w6 and w3 is w1, and the sum of w7 and w2 is w1. In the illustrated example, each of features 333, 334, 335 has the same length L1/3 but they may be different so long as they match the lengths of features 323, 324, 325. Other characteristics that provide an inverse of features 323, 324, 325 may be used.

FIG. 3E illustrates example line feature 300 with misalignment between portions 301, 302 thereof causing a gap between portions 301, 302, arranged in accordance with at least some implementations of the present disclosure. As shown, when x- and/or y-dimension misalignment between portions 301, 302 causes separation therebetween, a gap 351 having the same shape as shared edge 344 is formed between portions 301, 302 such that, in gap 351 no direct exposure may be provided. However, such gap 351 may still develop due to direct exposure in neighboring features 323, 324, 325, 333, 335, 335. Notably, the area of the lower concentration of photoacids caused by such misalignment is spread out over a greater area with respect to abutting line portions. Thereby, the same amount of misalignment does not cause the same difficulties in patterning line feature 300.

FIG. 3F illustrates example line feature 300 with misalignment between portions 301, 302 thereof causing an overlap between portions 301, 302, arranged in accordance with at least some implementations of the present disclosure. As shown, when x- and/or y-dimension misalignment between portions 301, 302 causes overlap therebetween, an overlap 352 having the same shape as shared edge 344 is formed between portions 301, 302 such that overlap 352 has an undesirable double exposure. However, by providing features 323, 324, 325, 333, 335, 335, such overlap 352 again distributes the higher concentration of photoacids over a greater area to reduce the undesirable impact of the overlap. Notably, in contrast to abutting line features, which will have jogs aligned in the y-dimension, resultant line feature 300 includes a first jog 361 offset from a second jog 362 by the length L1 of merged region 341. Such offsetting of the jogs 361, 362 provides for a more robust line feature 300 for improved reliability.

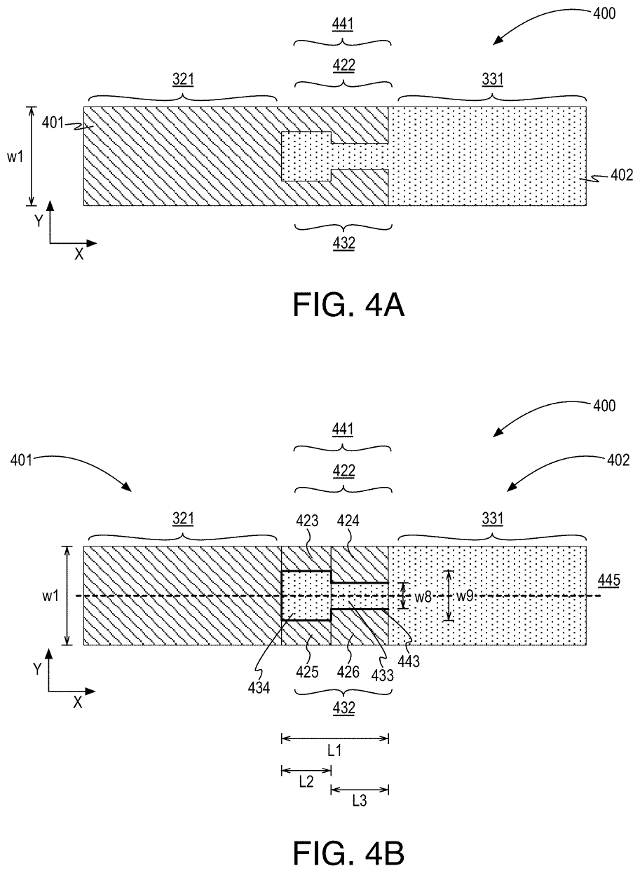

FIGS. 3A-3F illustrate example portions 301, 302 having inverse stair-step patterns in merged region 341. FIGS. 4A, 4B, 5A, 5B, 6A, 6B, 7A, 7B, 8A, and 8B illustrate alternative inverse patterns according to some embodiments. In such illustrations, the implementation within reticles, separate illustration of the portions, illustration of gaps and overlaps, and other characteristics are not repeated for the sake of brevity and clarity of disclosure. It will evident that any such characteristics discussed with respect to FIGS. 3A-3F may also apply to the patterns discussed with respect to FIGS. 4A, 4B, 5A, 5B, 6A, 6B, 7A, 7B, 8A, and 8B.

FIG. 4A illustrates an example line feature 400 generated by overlaying first and second portions 401, 402 deploying interlocking line end features, arranged in accordance with at least some implementations of the present disclosure. Line feature 400 may be fabricated by merging a first portion 401 from a first reticle and corresponding exposure and a second portion 402 from a second exposure using the first reticle or a second reticle.

First portion 401 includes first continuous feature or region 321 having width w1 along a length (in the x-dimension) thereof. As discussed, continuous region 321 is an uninterrupted region in an area defined by width w1 and the length of continuous region 321, which may extend in the x-dimension. Adjoining continuous region 321 is a region 422 of first portion 401. As shown, region 422 of first portion 401 has a receiving pattern to receive an interlocking pattern of region 432 of second portion 402. Second portion 402 of line feature 400 includes continuous region 331 having width w1 along a length thereof. Continuous region 331 is adjoined by region 432 of second portion 402. Region 432 of second portion 402 has an inverse pattern relative to the pattern of region 422 such that the pattern of region 432 and the pattern of region 422 merge to form a merged region 441 that, when regions 422, 432 are overlapped, is continuous and has no overlay regions.

FIG. 4B illustrates example portions 401, 402 of example line feature 400 showing segmented features thereof, arranged in accordance with at least some implementations of the present disclosure. In FIG. 4B, portion 401 is illustrated as segmented into rectangular region 321 and rectangular features 423, 424, 425, 426. Likewise, portion 402 is illustrated as segmented into rectangular region 331 and rectangular features 433, 434. Such segmentation is provided for the sake of clarity of presentation.

Portions 401, 402 have interlocking key and lock patterns such that, for portion 402, feature 433 adjoins region 331 and feature 434 adjoins feature 433 but not region 331. That is, feature 434 is separate from region 331 but coupled thereto via feature 433. As shown, feature 433 has a width w8 that is less than a width w9 of feature 434, thereby providing the interlocking key of the key and lock pattern. Furthermore, feature 434 has a length L2 and feature 433 has a length L3. In some embodiments, length L2 is the same as length L3 (i.e., L2=L3=½L1). However, different lengths may be employed. Furthermore, additional features between feature 433 and feature 433 may be used such that the intervening feature has a width greater than or less than w8 but typically les than width w9.

Region 422 of portion 401 has inverse features 423, 424, 425, 426 such that features 423, 434 fill the line width adjacent feature 434 and features 424, 426 fill the line width adjacent feature 433. In some embodiments, features 423, 425 have the same widths (i.e., w=½(w1−w9)). In some embodiments, the widths are different. Similarly features 424, 426 may have the same widths (i.e., w=½(w1−w8)) or they may be different. As shown, features 434, 433 may advantageously be toward a center axis 445 of merged region 441 and line feature 400. In some embodiments, region 331 and features 434, 433 share a center axis 445. As used herein, the term center axis indicates the feature or region is symmetric about the center axis in one direction. For example, region 331 and features 434, 433 are symmetrical about center axis 445, which extends in the x-dimension.

Line feature 400 may have any width w1 and merged region 441 may have any length L1 (or length relative to width w1, L1/w1) as discussed herein with respect to FIGS. 3A-3F. Widths w8, w9 of features 433, 434, respectively, may be any suitable proportion of width w1. In some embodiments, the ratio of width w9 to width w1 is about one-half. In some embodiments, the ratio of width w9 to width w1 is in the range of 0.35 to 0.6. In some embodiments, the ratio of width w9 to width w1 is in the range of 0.45 to 0.55. In some embodiments, the ratio of width w9 to width w1 is in the range of 0.45 to 0.7. In some embodiments, the ratio of width w8 to width w1 is about one-quarter. In some embodiments, the ratio of width w8 to width w1 is in the range of 0.15 to 0.35. In some embodiments, the ratio of width w8 to width w1 is in the range of 0.2 to 0.3. In some embodiments, the ratio of width w8 to width w1 is in the range of 0.25 to 0.45.

A shared boundary 443 is provided between portions 401, 402 within merged region 441. Shared boundary 443 advantageously increases the shared boundary length between portions 401, 402, relative to abutting line portions, to provide much smaller variations in photoacid concentrations when misalignment or distortion occurs. Shared boundary 443 may have any shared boundary length as a proportion of width w1 discussed herein. Furthermore, shared boundary 443 also illustrates that the lock and key pattern in merged region 441, provides, when misalignment occurs in any direction, a combination of gaps and overlays such that distribution of lower and higher concentrations is both expanded over a greater area and is to include areas of lower and higher concentrations in merged region 441. Thereby, improved patterning is provided in merged region 441 misalignment occurs.

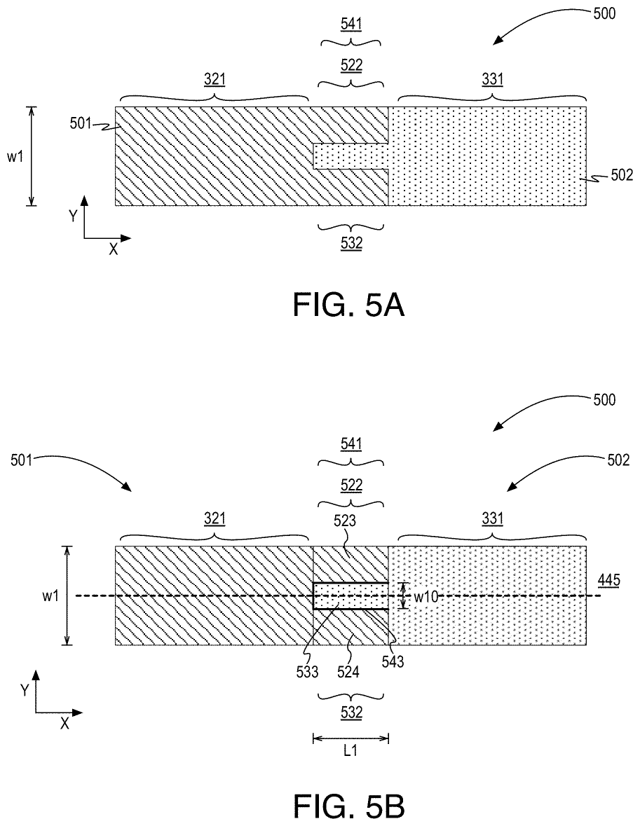

FIG. 5A illustrates an example line feature 500 generated by overlaying first and second portions 501, 502 deploying notch and tab line end features, arranged in accordance with at least some implementations of the present disclosure. Line feature 500 may be fabricated by merging a first portion 501 from a first reticle and corresponding exposure and a second portion 502 from a second exposure using the first reticle or a second reticle.

First portion 501 includes first continuous feature or region 321 having width w1 along a length (in the x-dimension) thereof. Continuous region 321 is adjoined by a region 522 of first portion 501 such that region 522 of first portion 501 has a receiving pattern or notch to receive an interlocking pattern or tab of region 532 of second portion 502. Second portion 502 of line feature 500 includes continuous region 331 having width w1 along a length thereof. Continuous region 331 is adjoined by region 532 of second portion 502. Region 532 of second portion 502 has an inverse pattern relative to the pattern of region 522 such that the pattern of region 532 and the pattern of region 522 merge to form a merged region 541 that, when regions 522, 532 are overlapped, is continuous and has no overlay regions.

FIG. 5B illustrates example portions 501, 502 of example line feature 500 showing segmented features thereof, arranged in accordance with at least some implementations of the present disclosure. In FIG. 5B, portion 501 is illustrated as segmented into rectangular region 321 and rectangular features 523, 524 and portion 502 is illustrated as segmented into rectangular region 331 and rectangular feature 533. Such segmentation is provided for the sake of clarity of presentation.

Portions 501, 502 have interlocking notch and tab patterns such that, for portion 502, feature 533 adjoins region 331. That is, feature 533 provides a notch in the notch and tab pattern. Feature 533 has a width w10 that is a fraction of width w1 of line feature 500. Furthermore, feature 533 has a length L1 matching that of merged region 541. Region 522 of portion 501 has inverse features 523, 524, such that feature 523, 524 fill the line width adjacent feature 533. In some embodiments, features 523, 524 have the same widths (i.e., w=½(w1−w10)). In some embodiments, they are different. As shown, feature 533 may advantageously be toward center axis 445 of merged region 541 and line feature 500, in some embodiments. For example, region 331 and feature 533 may have the same center axis 445.

Line feature 500 may have any width w1 and merged region 541 may have any length L1 (or length relative to width w1, L1/w1) as discussed herein. Width w10 of feature 533 may be any suitable proportion of width w1. In some embodiments, the ratio of width w10 to width w1 is about one-half. In some embodiments, the ratio of width w10 to width w1 is in the range of 0.35 to 0.6. In some embodiments, the ratio of width w10 to width w1 is in the range of 0.45 to 0.55. In some embodiments, the ratio of width w10 to width w1 is in the range of 0.45 to 0.7.

A shared boundary 543 is provided between portions 501, 502 within merged region 441 such that, as discussed, shared boundary 543 advantageously increases the shared boundary length between portions 501, 502, relative to abutting line portions, to reduce variations in photoacid concentrations when misalignment or distortion occurs. Shared boundary 543 may have any shared boundary length as a proportion of width w1 discussed herein. Furthermore, shared boundary 543 also illustrates that the notch and tab pattern in merged region 541, provides, when misalignment occurs in the y-direction, a combination of gaps and overlays such that distribution of lower and higher concentrations is both expanded over a greater area and is to include areas of lower and higher concentrations when y-direction misalignment occurs.

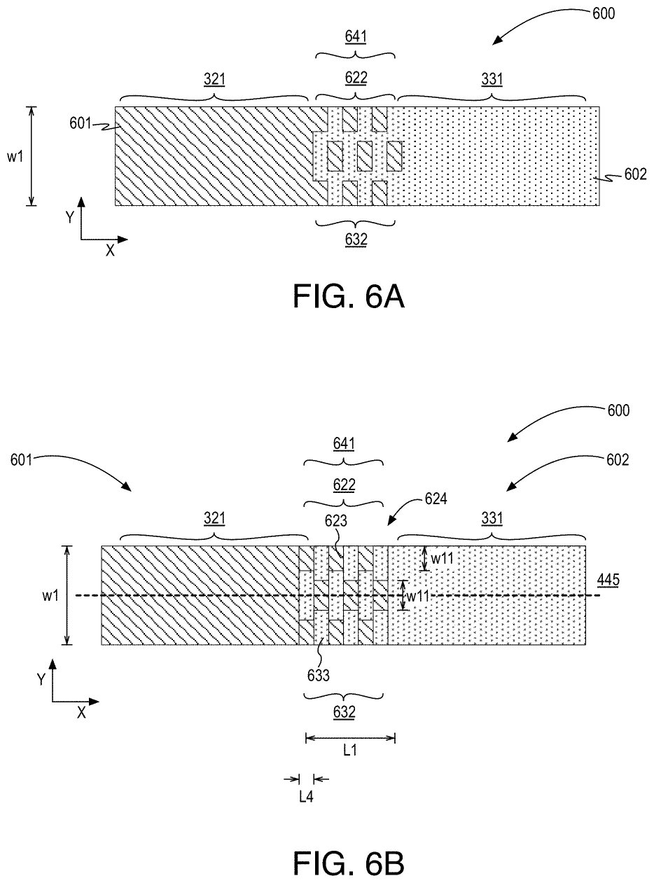

FIG. 6A illustrates an example line feature 600 generated by overlaying first and second portions 601, 602 deploying grid based line end features, arranged in accordance with at least some implementations of the present disclosure. Line feature 600 may be fabricated by merging a first portion 601 from a first reticle and corresponding exposure and a second portion 602 from a second exposure using the first reticle or a second reticle.

First portion 601 includes first continuous region 321 having width w1 and a region 622 of first portion 601 adjoining first continuous region 321. As shown, region 622 of first portion 601 has a grid pattern of features to interlock with a pattern of region 632 of second portion 602. Second portion 602 of line feature 600 includes continuous region 331 having width w1, and continuous region 331 is adjoined by region 632 of second portion 602. Region 632 of second portion 602 has an inverse pattern relative to the pattern of region 622 such that the pattern of region 632 and the pattern of region 622 merge to form a merged region 641 that, when regions 622, 632 are overlapped, is continuous and has no overlay regions.

FIG. 6B illustrates example portions 601, 602 of example line feature 600 showing segmented features thereof, arranged in accordance with at least some implementations of the present disclosure. In FIG. 6B, portion 601 is illustrated as segmented into rectangular region 321 and rectangular features 623. Likewise, portion 602 is illustrated as segmented into rectangular region 331 and rectangular features 633. Such segmentation is provided for the sake of clarity of presentation.

Portions 601, 602 have interlocking grid patterns such that, for portion 601, two of features 623 adjoin region 321 and other of features 623 are separate from region 331 and other ones of features 623. As shown, features 623 are formed in a grid pattern 624. In the illustrated example, features 623 are provided in an offset grid pattern 624 such that, for adjacent columns of grid pattern 624, features 623 are offset from one another in the y-dimension and, for alternating columns of grid pattern 624, features 623 are aligned. As shown, features 623 have a width w11 that is a fraction of width w1 of line feature 600. Furthermore, features 623 have a length L4 that is a fraction of length L1 of merged region 641.

Region 632 of portion 601 has inverse features 633 such that features 633 provide an inverse grid pattern relative to grid pattern 624. That is, features 633 fill the line width adjacent feature 623. In some embodiments, for odd columns of features 633, features 633 have a width of the width of line feature 600 less twice the width of features 623 (i.e., w=w1−2*w11) and, for even columns of features 633, features 633 have a width of the width of line feature 600 less the width of features 623, halved (i.e., w=(w1−w11)/2). Although illustrated with offset grid pattern 624 other grid patterns may be used such as a normalized grid of equal sized and pitched features, or the like. In the illustrated example, grid pattern 624 is symmetric about center axis 445.

Line feature 600 may have any width w1 and merged region 641 may have any length L1 (or length relative to width w1, L1/w1) discussed herein. Widths w11 of features 623 may be any suitable proportion of width w1. In some embodiments, the ratio of width w11 to width w1 is about one-quarter. In some embodiments, the ratio of width w11 to width w1 is in the range of 0.15 to 0.35. In some embodiments, the ratio of width w11 to width w1 is in the range of 0.2 to 0.3. In some embodiments, the ratio of width w11 to width w1 is in the range of 0.25 to 0.4.

A shared boundary (not shown) is provided between portions 601, 602 within merged region 641 in analogy to other shared boundaries discussed herein to advantageously increase the shared boundary length between portions 601, 602, relative to abutting line portions. The shared boundary between portions 601, 602 provides smaller variations in photoacid concentrations when misalignment or distortion occurs. The shared boundary may have any shared boundary length as a proportion of width w1 discussed herein. Furthermore, the shared boundary between portions 601, 602 provides, when misalignment occurs in any direction, a combination of gaps and overlays such that distribution of lower and higher concentrations is both expanded over a greater area and is to include areas of lower and higher concentrations in merged region 441.

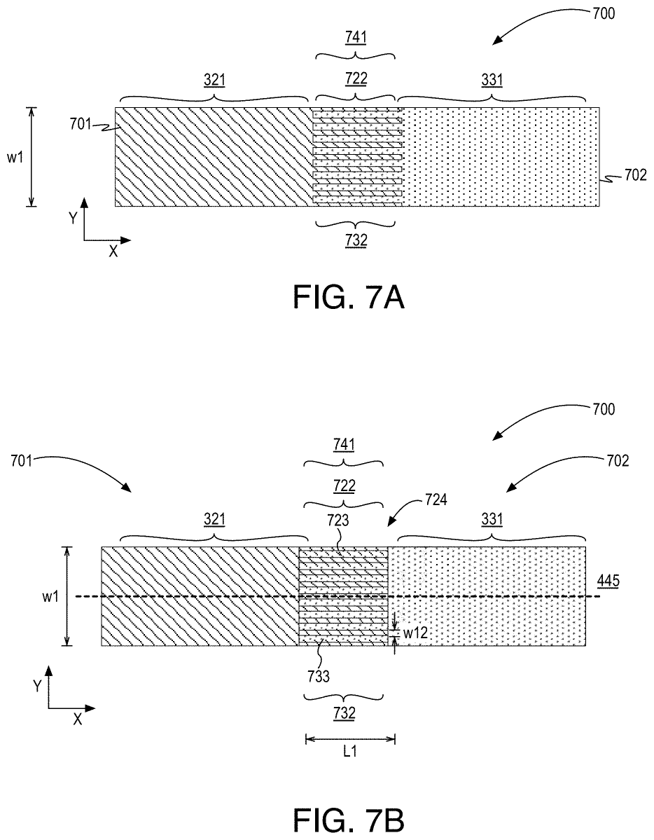

FIG. 7A illustrates an example line feature 700 generated by overlaying first and second portions 701, 702 deploying parallel linear end features, arranged in accordance with at least some implementations of the present disclosure. Line feature 700 may be fabricated by merging a first portion 701 from a first reticle and corresponding exposure and a second portion 702 from a second exposure using the first reticle or a second reticle. First portion 701 includes first continuous region 321 having width w1 and a region 722 adjoining first continuous region 321. As shown, region 722 includes linear features parallel to continuous region 321 to interlock with a pattern of region 732 of second portion 702. Second portion 702 of line feature 700 includes continuous region 331 having width w1, and continuous region 331 is adjoined by region 732 of second portion 702. Regions 722, 732 have inverse patterns relative to one another such that the pattern of region 732 and the pattern of region 722 merge to form a merged region 741 that, when regions 722, 732 are overlapped, is continuous and has no overlay regions.

FIG. 7B illustrates example portions 701, 702 of example line feature 700 showing segmented features thereof, arranged in accordance with at least some implementations of the present disclosure. In FIG. 7B, portion 701 is illustrated as segmented into rectangular region 321 and rectangular features 723. Likewise, portion 702 is illustrated as segmented into rectangular region 331 and rectangular features 733 with such segmentation being provided for the sake of clarity of presentation.

Portions 701, 702 have interlocking linear patterns such that, for portion 701, a number of features 723 adjoin and extend from region 321. Features 723 are linear and extend across region 722 to provide a linear array pattern 724. As shown, features 723 are formed in an linear array and region 732 of portion 701 has inverse features 733 such that features 733 provide an inverse linear array pattern relative to the linear array pattern 724. That is, features 733 fill the line width adjacent and between features 723. As shown, linear features 723, 733 are aligned with center axis 445. Line feature 700 may have any width w1 and merged region 741 may have any length L1 (or length relative to width w1, L1/w1) discussed herein. Widths w12 of features 723 may be any suitable proportion of width w1. In some embodiments, the ratio of width w12 to width w1 is about one-tenth. In some embodiments, the ratio of width w12 to width w1 is in the range of 0.05 to 0.25. In some embodiments, the ratio of width w12 to width w1 is in the range of 0.1 to 0.2. In some embodiments, the ratio of width w12 to width w1 is in the range of 0.15 to 0.3. Each of features 723 may have the same width or they may be different. Furthermore, features 723 may be provided at a constant pitch about equal to twice width w12 (as illustrated) or the pitch may be varied.

A shared boundary (not shown) is again provided between portions 701, 702 within merged region 741 to advantageously increase the shared boundary length between portions 701, 702, relative to abutting line portions. The shared boundary between portions 701, 702 provides smaller variations in photoacid concentrations when misalignment or distortion occurs as discussed herein.

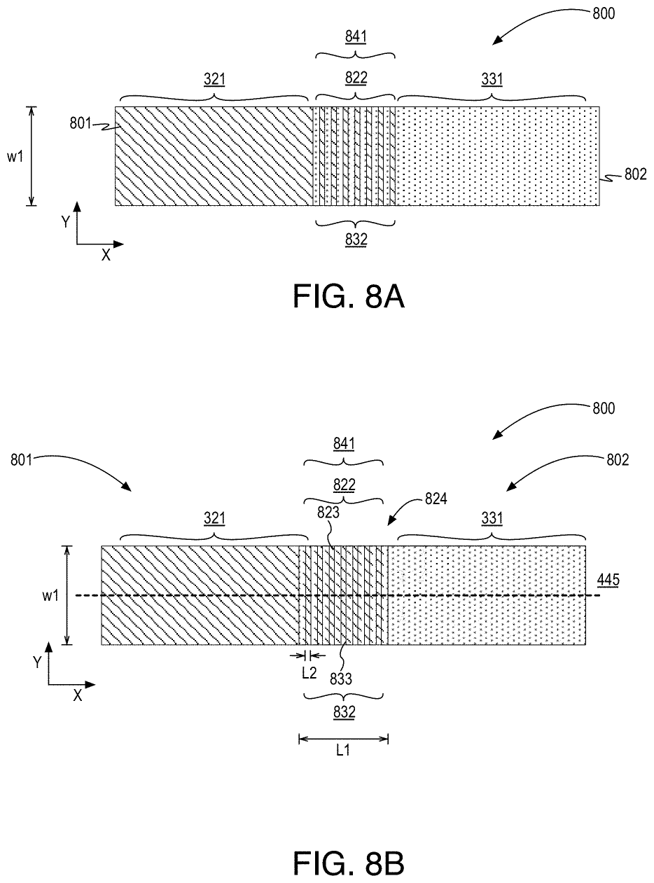

FIG. 8A illustrates an example line feature 800 generated by overlaying first and second portions 801, 802 deploying orthogonal linear end features, arranged in accordance with at least some implementations of the present disclosure. Line feature 800 may be fabricated by merging a first portion 801 from a first reticle and corresponding exposure and a second portion 802 from a second exposure using the first reticle or a second reticle. First portion 801 includes first continuous region 321 having width w1 and a region 822 adjoining and adjacent first continuous region 321. As shown, region 822 includes linear features orthogonal to continuous region 321 to interlock with a pattern of region 832 of second portion 802. Second portion 802 of line feature 800 includes continuous region 331 having width w1, with continuous region 331 is adjoined by region 832 of second portion 802. Regions 822, 832 have inverse patterns relative to one another such that the pattern of region 832 and the pattern of region 822 merge to form a merged region 841 that, when regions 822, 832 are overlapped, is continuous and has no overlay regions.

FIG. 8B illustrates example portions 801, 802 of example line feature 800 showing segmented features thereof, arranged in accordance with at least some implementations of the present disclosure. In FIG. 8B, portion 801 is illustrated as segmented into rectangular region 321 and rectangular features 823 and portion 802 is illustrated as segmented into rectangular region 331 and rectangular features 833 with such segmentation being provided for the sake of clarity of presentation.

Portions 801, 802 have interlocking linear patterns such that, for portion 801, a number of features 823 adjoin and/or are adjacent from region 321. Features 823 are linear and extend across region 822 orthogonal to central axis 445 to provide a linear array pattern 824. As shown, features 823 are formed in an linear array and region 832 of portion 801 has inverse features 833 such that features 833 provide an inverse orthogonal linear array pattern relative to the orthogonal linear array pattern 824. That is, features 833 fill the line length adjacent and between features 823. As shown, linear features 823, 833 are orthogonal to center axis 445. Line feature 800 may have any width w1 and merged region 841 may have any length L1 (or length relative to width w1, L1/w1) discussed herein. Lengths L2 of features 823 may be any suitable proportion of width w1. In some embodiments, the ratio of width L2 to width w1 is about one-tenth. In some embodiments, the ratio of width L2 to width w1 is in the range of 0.05 to 0.25. In some embodiments, the ratio of width L2 to width w1 is in the range of 0.1 to 0.2. In some embodiments, the ratio of width L2 to width w1 is in the range of 0.15 to 0.3. Each of features 823 may have the same width or they may be different. Furthermore, features 823 may be provided at a constant pitch about equal to twice width L2 (as illustrated) or the pitch may be varied.

A shared boundary (not shown) is again provided between portions 801, 802 within merged region 841 to advantageously increase the shared boundary length between portions 801, 802, relative to abutting line portions.

As will be appreciated, the use of inverse or complementary line end patterns for improved reticle stitching or exposure stitching are not limited to the patterns and designs disclosed herein. Other patterns or interfaces (such as more complex patterns having more features, features of varying shapes, non-rectilinear boundaries, etc.) may be used to provide highly diffuse boundaries between portions of line features in merged regions (i.e., a stitched region). Such designs and patterns result in more diffuse boundaries for patterning robustness in reticle stitching or exposure stitching.

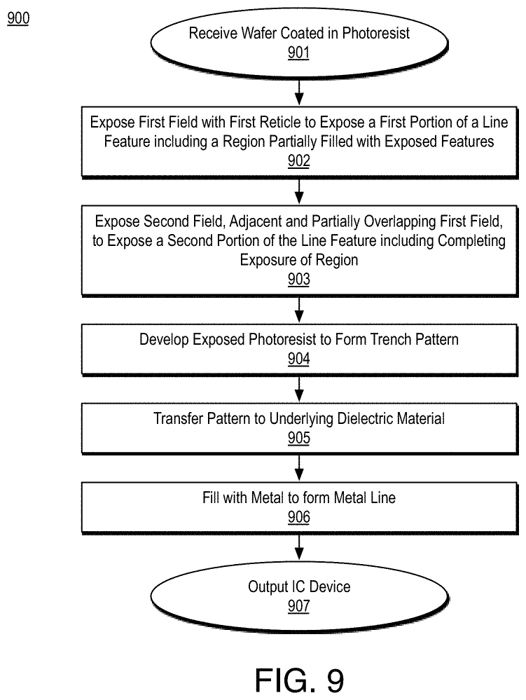

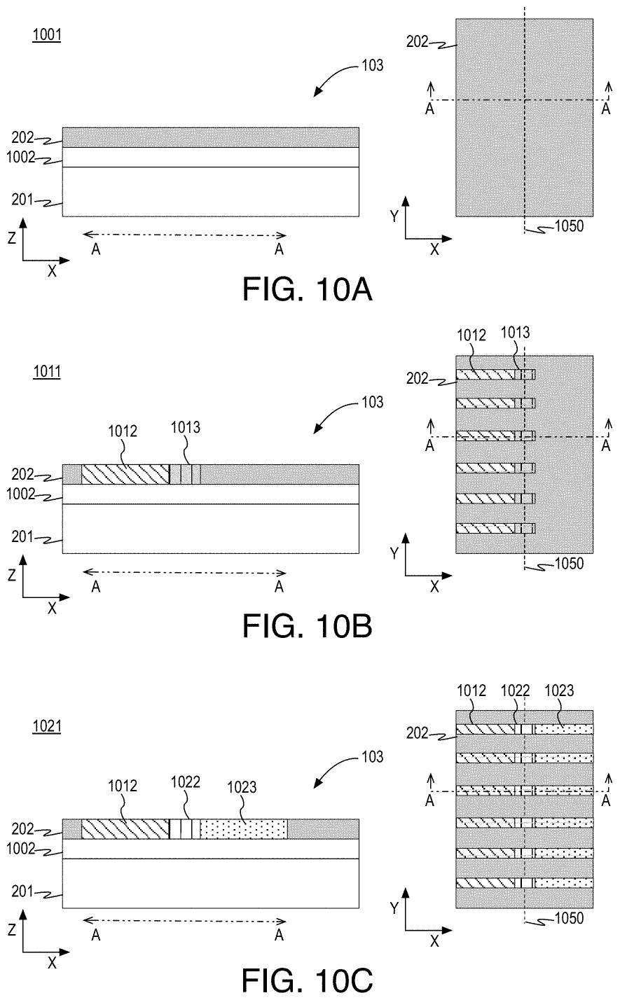

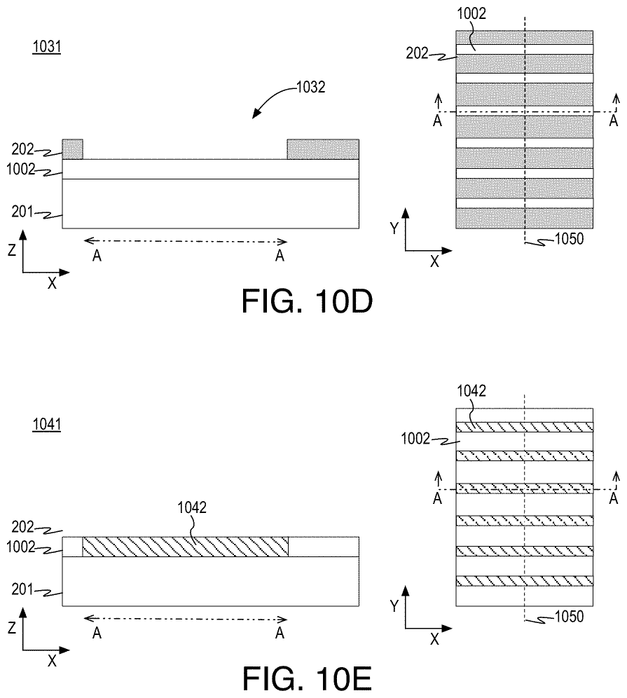

FIG. 9 is a flow diagram illustrating an example process 900 for fabricating an integrated circuit device, arranged in accordance with at least some implementations of the present disclosure. For example, process 900 may be implemented to fabricate device structures illustrated in FIGS. 10A-10E.

FIGS. 10A, 10B, 10C, 10D, and 10E are views of example integrated circuit device structures as particular fabrication operations are performed, arranged in accordance with at least some implementations of the present disclosure.

With reference to FIG. 9, process 900 begins at operation 901, where a wafer coated in photoresist is received for processing. The wafer may include any suitable substrate material. For example, the substrate may include a semiconductor material such as monocrystalline silicon (Si), germanium (Ge), silicon germanium (SiGe), a III-V materials based material (e.g., gallium arsenide (GaAs)), a silicon carbide (SiC), a sapphire (Al₂O₃), or any combination thereof. The wafer may further include, in, on, and/or over the substrate, a device layer and one or more metallization layers. The device layer may include transistors, memory devices, capacitors, resistors, optoelectronic devices, switches, or any other active or passive electronic devices, or portions thereof. the metallization layer(s) may include via layers and metal line layers to interconnect and provide access to the devices. The wafer is coated with a photoresist layer for patterning operations. The photoresist layer may include any suitable photoresist such as a positive photoresist material.

FIG. 10A illustrates a cross-sectional and top-down views of an integrated circuit device structure 1001 after the formation of photoresist layer 202 on a dielectric layer 1002 over substrate 201. In FIG. 10A and FIGS. 10B, 10C, 10D, and 10E, the left side provide a cross sectional view of a portion of integrated circuit device structure 1001 and the right side provides a top down view of portion A-A across a field boundary 1050. As discussed, substrate 201 may include any material(s) such as monocrystalline silicon, germanium, silicon germanium, a III-V materials based material (e.g., gallium arsenide), a silicon carbide, a sapphire, or the like. A device layer of substrate 201 may include any devices such as transistors, memory devices, capacitors, resistors, optoelectronic devices, switches, or any other active or passive electronic devices. Such devices are fabricated using known techniques such as lithography, etch, deposition, implant, etc. Dielectric layer 1002 is over substrate 201. For example, substrate 201 may include metallization layers at a top thereof that are to be contacted by reticle stitched metal lines formed in dielectric layer 1002 using single damascene or dual damascene techniques.

Returning to FIG. 9, processing continues at operation 902, where a first field of the substrate is exposed using a first reticle such that a first portion of a line feature is exposed with the first portion including a region partially filled with exposed features. The first reticle and first portion may include any portions discussed herein such as any of portions 301, 302, 401, 402, 501, 502, 601, 602, 701, 702, 801, 802. Notably, the region partially filled with exposed features exposes parts or features of the region as discussed herein. The region may have a stair-step pattern, a lock or key pattern, a tab or notch pattern, a grid pattern, a line pattern, or the like.

FIG. 10B illustrates an integrated circuit device structure 1011 similar to integrated circuit device structure 1001 after patterning a first portion of a line feature. As shown, after the first exposure, region 1012 of photoresist layer 202 is fully exposed and features with region 1013 are exposed such that a part or parts of region 1013 and inverse parts are not exposed. Region 1013 may match any region of any line feature portion discussed herein such as any of regions 322, 332, 422, 432, 522, 532, 622, 632, 722, 732, 822, 832. As shown, regions 1013 straddle or extend across field boundary 1050.

Returning to FIG. 9, processing continues at operation 903, where a second field, adjacent and partially overlapping the first field exposed in operation 902, of the substrate is exposed using the first reticle or a second reticle such that a second portion of the line feature is exposed with the exposure of the second portion completing exposure of the region that was partially filled with exposed features at operation 902. For example, the second portion incudes an inverse pattern of the exposed region. The first or second reticle and second portion may include any portions discussed herein such as the inverse ones of portions 301, 302, 401, 402, 501, 502, 601, 602, 701, 702, 801, 802 as patterned at operation 902. Notably, the remaining areas or features of the region that was partially exposed features at operation 902 are exposed, ideally without gaps or overlaps. The region exposed at operation 903 may have the inverse of any of the stair-step pattern, lock or key pattern, tab or notch pattern, grid pattern, or line pattern, or the like exposed at operation 902.

FIG. 10C illustrates an integrated circuit device structure 1021 similar to integrated circuit device structure 1011 after patterning a second portion of the line feature. As shown, the second exposure fully exposes region 1023 of photoresist layer 202 and completes the exposure of merged region 1022 of photoresist layer 202. The inverse pattern patterned to complete exposure of merged region 1022 may be the matching inverse or complement pattern of any region of any line feature portion discussed herein such as any of regions 322, 332, 422, 432, 522, 532, 622, 632, 722, 732, 822, 832 as discussed herein. As shown, merged regions 1022 straddle or extend across field boundary 1050. Although illustrated with different patterns for the sake of clarity of presentation exposed region 1012, merged region 1022, and exposed region 1023 are now all fully exposed photoresist substantially sharing the same properties.

Returning to FIG. 9, processing continues at operation 904, where the exposed photoresist is developed to form trench patterns in the photoresist layer. The exposed photoresist may be developed using any suitable technique or techniques that remove the exposed portions of the photoresist and leave unexposed portions of the photoresist. As discussed, the exposure of photoresist regions generates photoacids that break down the resist polymer making it soluble in a developer solution.

FIG. 10D illustrates an integrated circuit device structure 1031 similar to integrated circuit device structure 1021 after developing photoresist layer 202. As shown, after develop, photoresist layer 202 includes a trench pattern 1032 in photoresist layer 202. Trench pattern 1032 may include any pattern inclusive of exposed region 1012, merged region 1022, and exposed region 1023. Deployment of line end patterns discussed herein facilitates improved patterning of photoresist layer 202.

Returning to FIG. 9, processing continues at operation 905, where the pattern in the photoresist layer is transferred to an underlying dielectric material. The pattern in the photoresist layer may be transferred to the underlying dielectric material using any suitable technique or techniques such as etch techniques. Although illustrated herein with respect to transfer of the pattern in the photoresist layer to a dielectric material for the formation of an eventual metal line, the pattern in the photoresist layer may be used in any suitable fabrication processing.

Processing continues at operation 906, where the pattern in the dielectric material is filled with a metal or metals to form a metal signal line of an integrated circuit device. The metal line may be formed using any suitable technique or techniques such as application of a liner material (e.g., titanium nitride, tantalum nitride, or the like), followed by bulk metal fill (e.g., copper fill), which may be followed by planarization techniques. Other metal fill materials and/or processing may be used.

Processing continues at operation 907, where an integrated circuit device including reticle stitched metal lines is output. For example, a die including multiple fields connected by reticle stitched metal lines may be segmented from a remainder of the substrate (i.e., substrate wafer), packaged, and so on, and eventually included in an electronic device.

FIG. 10E illustrates an integrated circuit device structure 1041 similar to integrated circuit device structure 1021 after the removal of photoresist layer 202 (e.g., using ash processing) and formation of metal line 1042 a trench of dielectric. As shown, metal line 1042 (and optional liner, not shown) are formed in a trench of dielectric layer 1002. Metal line 1042 may be formed using any suitable technique or techniques. In some embodiments, dielectric layer 1002 is patterned resultant trench pattern 1032 (i.e., using etch techniques) to form a trench in trench pattern 1032 and forming metal line 1042 in the trench.

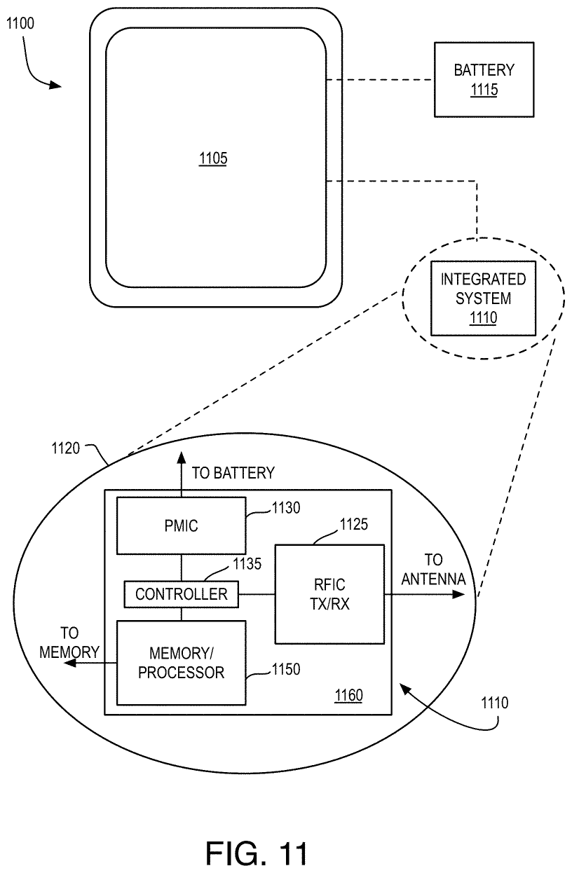

FIG. 11 is an illustrative diagram of a mobile computing platform 1100 employing an integrated circuit die having reticle stitched metal lines, arranged in accordance with at least some implementations of the present disclosure. Any device or structure having any components, materials, or characteristics discussed herein may be implemented by any component of mobile computing platform 1100. Mobile computing platform 1100 may be any portable device configured for each of electronic data display, electronic data processing, wireless electronic data transmission, or the like. For example, mobile computing platform 1100 may be any of a tablet, a smart phone, a netbook, a laptop computer, etc. and may include a display screen 1105, which in the exemplary embodiment is a touchscreen (e.g., capacitive, inductive, resistive, etc. touchscreen), a chip-level (system on chip—SoC) or package-level integrated system 1110, and a battery 1115. Battery 1115 may include any suitable device for providing electrical power such as a device consisting of one or more electrochemical cells and electrodes to couple to an outside device. Mobile computing platform 1100 may further include a power supply to convert a source power from a source voltage to one or more voltages employed by other devices of mobile computing platform 1100.

Integrated system 1110 is further illustrated in the expanded view 1120. In the exemplary embodiment, packaged device 1150 (labeled “Memory/Processor” in FIG. 11) includes at least one memory chip (e.g., RAM), and/or at least one processor chip (e.g., a microprocessor, a multi-core microprocessor, or graphics processor, or the like). In an embodiment, the package device 1150 is a microprocessor including an SRAM cache memory. As shown, device 1150 may employ a die or device having any transistor structures and/or related characteristics discussed herein. Packaged device 1150 may be further coupled to (e.g., communicatively coupled to) a board, a substrate, or an interposer 1160 along with, one or more of a power management integrated circuit (PMIC) 1130, RF (wireless) integrated circuit (RFIC) 1125 including a wideband RF (wireless) transmitter and/or receiver (TX/RX) (e.g., including a digital baseband and an analog front end module further comprises a power amplifier on a transmit path and a low noise amplifier on a receive path), and a controller 1135 thereof. In general, packaged device 1150 may be also be coupled to (e.g., communicatively coupled to) display screen 1105. As shown, one or both of PMIC 1130 and/or RFIC 1125 may employ a die or device having any transistor structures and/or related characteristics discussed herein.

Functionally, PMIC 1130 may perform battery power regulation, DC-to-DC conversion, etc., and so has an input coupled to battery 1115 and with an output providing a current supply to other functional modules. In an embodiment, PMIC 1130 may perform high voltage operations. As further illustrated, in the exemplary embodiment, RFIC 1125 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. In alternative implementations, each of these board-level modules may be integrated onto separate ICs coupled to the package substrate of packaged device 1150 or within a single IC (SoC) coupled to the package substrate of the packaged device 1150.

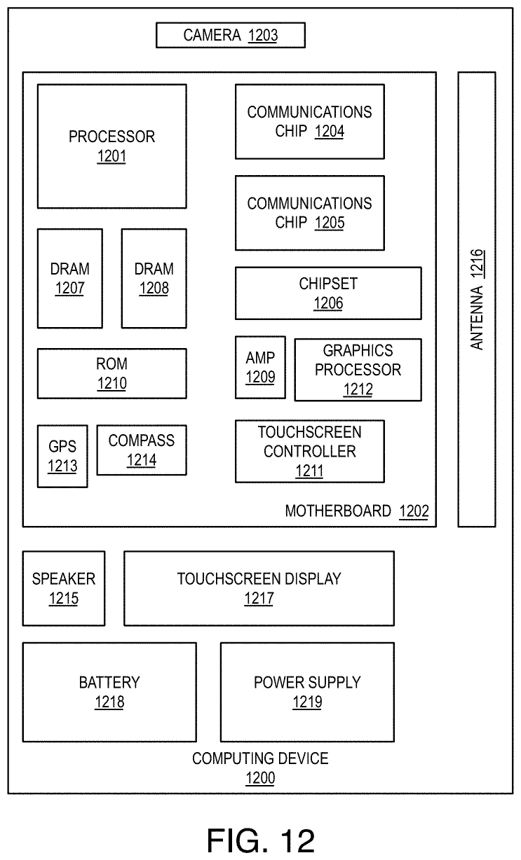

FIG. 12 is a functional block diagram of a computing device 1200, arranged in accordance with at least some implementations of the present disclosure. Computing device 1200 may be found inside platform 1100, for example, and further includes a motherboard 1202 hosting a number of components, such as but not limited to a processor 1201 (e.g., an applications processor) and one or more communications chips 1204, 1205. Processor 1201 may be physically and/or electrically coupled to motherboard 1202. In some examples, processor 1201 includes an integrated circuit die packaged within the processor 1201. In general, the term “processor” may refer to any device or portion of a device that processes electronic data from registers and/or memory to transform that electronic data into other electronic data that may be stored in registers and/or memory. Any one or more device or component of computing device 1200 may include a die, metal line, or any other structure with any related characteristics discussed herein.

In various examples, one or more communication chips 1204, 1205 may also be physically and/or electrically coupled to the motherboard 1202. In further implementations, communication chips 1204 may be part of processor 1201. Depending on its applications, computing device 1200 may include other components that may or may not be physically and electrically coupled to motherboard 1202. These other components may include, but are not limited to, volatile memory (e.g., DRAM) 1207, 1208, non-volatile memory (e.g., ROM) 1210, a graphics processor 1212, flash memory, global positioning system (GPS) device 1213, compass 1214, a chipset 1206, an antenna 1216, a power amplifier 1209, a touchscreen controller 1211, a touchscreen display 1217, a speaker 1215, a camera 1203, a battery 1218, and a power supply 1219, as illustrated, and other components such as a digital signal processor, a crypto processor, an audio codec, a video codec, an accelerometer, a gyroscope, and a mass storage device (such as hard disk drive, solid state drive (SSD), compact disk (CD), digital versatile disk (DVD), and so forth), or the like.

Communication chips 1204, 1205 may enable wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1204, 1205 may implement any of a number of wireless standards or protocols, including but not limited to those described elsewhere herein. As discussed, computing device 1200 may include a plurality of communication chips 1204, 1205. For example, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others. Furthermore, power supply 1219 may convert a source power from a source voltage to one or more voltages employed by other devices of mobile computing platform 1100. In some embodiments, power supply 1219 converts an AC power to DC power. In some embodiments, power supply 1219 converts an DC power to DC power at one or more different (lower) voltages. In some embodiments, multiple power supplies are staged to convert from AC to DC and then from DC at a higher voltage to DC at a lower voltage as specified by components of computing device 1200.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

The following embodiments pertain to further embodiments.

In one or more first embodiments, a reticle set comprises first and second lithographic reticles comprising first and second patterns, respectively, wherein the first pattern comprises a first portion of a line feature, the first portion comprising a continuous first region having a first width and a second region adjoining the first region, the second region comprising one or more first pattern features, and wherein the second pattern comprises a second portion of the line feature, the second portion comprising a continuous third region having the first width and a fourth region adjoining the third region, wherein, when overlaid, the second and fourth regions provide a substantially continuous merged region.

In one or more second embodiments, further to the first embodiment, each of the first pattern features has a different width less than the first width, and the first region and each of the first pattern features comprise a shared edge.

In one or more third embodiments, further to the first or second embodiments, the first pattern features comprise a first feature adjoining the first region, a second feature adjoining the first feature, and a third feature adjoining the second feature, the first feature having a first width greater than a second width of the second feature, and the second width greater than a third width of the third feature.

In one or more fourth embodiments, further to any of the first through third embodiments, the first pattern features comprise a first feature adjoining the first region, and a second feature adjoining the first feature but not the first region, the first feature having a first width less than a second width of the second feature.

In one or more fifth embodiments, further to any of the first through fourth embodiments, the first region, first feature, and second feature are aligned along a shared center axis of the first region, first feature, and second feature.

In one or more sixth embodiments, further to any of the first through fifth embodiments, the first pattern features comprise a single feature adjoining the first region, the single feature centered on a center axis of the first region and having a width less than the first width.

In one or more seventh embodiments, further to any of the first through sixth embodiments, the first pattern features comprise a grid of first features within the second region.

In one or more eighth embodiments, further to any of the first through seventh embodiments, the first pattern features comprise a plurality of linear first features each extending across the second region.

In one or more ninth embodiments, further to any of the first through eighth embodiments, the linear first features are aligned a central axis of the first region.

In one or more tenth embodiments, further to any of the first through ninth embodiments, the merged region has substantially the first width, and such that a shared boundary between the first and second pattern features has a shared boundary length of not less than 1.75 times the constant first width.

In one or more eleventh embodiments, further to any of the first through tenth embodiments, the shared boundary length is not less than three times the constant first width.

In one or more twelfth embodiments, further to any of the first through eleventh embodiments, the first lithographic reticle comprises a first substantially opaque mask on a first transparent substrate, the first pattern defined in the first transparent substrate by the first opaque mask.

In one or more thirteenth embodiments, a lithographic reticle comprises a transparent substrate and a substantially opaque mask on the transparent substrate, the opaque mask defining a pattern in the transparent substrate, such that the pattern comprises a first portion of a line feature, the first portion adjacent and orthogonal to a first edge of the lithographic reticle, the first portion comprising a continuous first region and a second region adjoining the first region, the second region adjacent the first edge and comprising a first pattern, and such that the pattern comprises a second portion of the line feature, the second portion adjacent and orthogonal to a second edge of the lithographic reticle opposite the first edge, the second portion comprising a continuous third region and a fourth region adjoining the third region, the fourth region adjacent to the second edge and comprising an inverse pattern of the first pattern of the second region.

In one or more fourteenth embodiments, further to the thirteenth embodiment, the first pattern features comprise a plurality of features sharing an edge along the length of the line feature with the first region and arranged in a stair-step pattern with widths of the features decreasing moving away from the first region.

In one or more fifteenth embodiments, further to the thirteenth or fourteenth embodiments, the first pattern features comprise one or more features having a shared center axis with the first region.

In one or more sixteenth embodiments, further to any of the thirteenth through fifteenth embodiments, the first pattern features comprise a grid of first features within the second region.

In one or more seventeenth embodiments, further to any of the thirteenth through sixteenth embodiments, the first pattern features comprise a plurality of linear first features each extending across the second region.

In one or more eighteenth embodiments, a method comprises exposing a first field of a photoresist layer over a substrate wafer using a first reticle, said exposing the first field to expose a portion of a line feature in the photoresist layer, the line feature to have a substantially constant first width along a length thereof, the exposed portion comprising an exposed continuous first region and a second region adjoining the first region, the second region comprising one or more exposed first pattern features among unexposed first pattern features, exposing a second field of the photoresist layer partially overlapping the first field using the first reticle or a second reticle, said exposing the second field to expose the unexposed first pattern features and a third region of the line feature while not exposing the exposed first pattern features, and developing the photoresist layer to form a resultant trench pattern corresponding to the line feature.

In one or more nineteenth embodiments, further to the eighteenth embodiment, the exposed first pattern features comprise a first exposed feature having a first width adjoining the exposed continuous first region, a second exposed feature having a second width adjoining the first exposed feature, and a third exposed feature having a third width adjoining the second exposed feature, such that the exposed continuous first region and each of the first, second, and third exposed features comprise a shared edge, the third width is less than the second width, and the second width is less than the first width.

In one or more twentieth embodiments, further to the eighteenth or nineteenth embodiments, the exposed first pattern features comprise a first exposed feature having a first width adjoining the exposed continuous first region and a second exposed feature having a second width adjoining the first exposed feature but not the exposed continuous first region, such that the second width is greater than the first width and the exposed continuous first region, first exposed feature, and second exposed feature are aligned along a shared center axis of the exposed continuous first region, first exposed feature, and second exposed feature.

In one or more twenty-first embodiments, further to any of the eighteenth through twentieth embodiments, the exposed first pattern features comprise a grid of first exposed features within the first region.

In one or more twenty-second embodiments, further to any of the eighteenth through twenty-first embodiments, a shared boundary between the exposed first pattern features and the unexposed first pattern features has a first boundary length that is not less than 1.75 times the constant first width.

In one or more twenty-third embodiments, further to any of the eighteenth through twenty-second embodiments, the method further comprises patterning a dielectric layer using the resultant trench pattern to form a trench in the dielectric layer and forming a metal line in the trench.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. A lithographic reticle set, comprising:
first and second lithographic reticles comprising first and second patterns, respectively, wherein
the first pattern comprises a first portion of a line feature, the first portion comprising a continuous first region having a first width and a second region adjoining the first region, the second region comprising one or more first pattern features, and wherein
the second pattern comprises a second portion of the line feature, the second portion comprising a continuous third region having the first width and a fourth region adjoining the third region, wherein, when overlaid, the second and fourth regions provide a substantially continuous merged region.

2. The lithographic reticle set of claim 1, wherein each of the first pattern features has a different width less than the first width, and the first region and each of the first pattern features comprise a shared edge.

3. The lithographic reticle set of claim 2, wherein the first pattern features comprise a first feature adjoining the first region, a second feature adjoining the first feature, and a third feature adjoining the second feature, the first feature having a first width greater than a second width of the second feature, and the second width greater than a third width of the third feature.

4. The lithographic reticle set of claim 1, wherein the first pattern features comprise a first feature adjoining the first region, and a second feature adjoining the first feature but not the first region, the first feature having a first width less than a second width of the second feature.

5. The lithographic reticle set of claim 4, wherein the first region, first feature, and second feature are aligned along a shared center axis of the first region, first feature, and second feature.

6. The lithographic reticle set of claim 1, wherein the first pattern features comprise a single feature adjoining the first region, the single feature centered on a center axis of the first region and having a width less than the first width.

7. The lithographic reticle set of claim 1, wherein the first pattern features comprise a grid of first features within the second region.

8. The lithographic reticle set of claim 1, wherein the first pattern features comprise a plurality of linear first features each extending across the second region.

9. The lithographic reticle set of claim 8, wherein the linear first features are aligned a central axis of the first region.

10. The lithographic reticle set of claim 1, wherein the merged region has substantially the first width, and wherein a shared boundary between the first and second pattern features has a shared boundary length of not less than 1.75 times the constant first width.

11. The lithographic reticle set of claim 10, wherein the shared boundary length is not less than three times the constant first width.

12. The lithographic reticle set of claim 1, wherein the first lithographic reticle comprises a first substantially opaque mask on a first transparent substrate, the first pattern defined in the first transparent substrate by the first opaque mask.

13. A lithographic reticle, comprising:
a transparent substrate; and
a substantially opaque mask on the transparent substrate, the opaque mask defining a pattern in the transparent substrate, wherein
the pattern comprises a first portion of a line feature, the first portion adjacent and orthogonal to a first edge of the lithographic reticle, the first portion comprising a continuous first region and a second region adjoining the first region, the second region adjacent the first edge and comprising a first pattern, and wherein
the pattern comprises a second portion of the line feature, the second portion adjacent and orthogonal to a second edge of the lithographic reticle opposite the first edge, the second portion comprising a continuous third region and a fourth region adjoining the third region, the fourth region adjacent to the second edge and comprising an inverse pattern of the first pattern of the second region.

14. The lithographic reticle of claim 13, wherein the first pattern features comprise a plurality of features sharing an edge along the length of the line feature with the first region and arranged in a stair-step pattern with widths of the features decreasing moving away from the first region.

15. The lithographic reticle of claim 13, wherein the first pattern features comprise one or more features having a shared center axis with the first region.

16. The lithographic reticle of claim 13, wherein the first pattern features comprise a grid of first features within the second region.

17. The lithographic reticle of claim 13, wherein the first pattern features comprise a plurality of linear first features each extending across the second region.

18. A method, comprising:
exposing a first field of a photoresist layer over a substrate wafer using a first reticle, said exposing the first field to expose a portion of a line feature in the photoresist layer, the line feature to have a substantially constant first width along a length thereof, the exposed portion comprising an exposed continuous first region and a second region adjoining the first region, the second region comprising one or more exposed first pattern features among unexposed first pattern features;
exposing a second field of the photoresist layer partially overlapping the first field using the first reticle or a second reticle, said exposing the second field to expose the unexposed first pattern features and a third region of the line feature while not exposing the exposed first pattern features; and
developing the photoresist layer to form a resultant trench pattern corresponding to the line feature.

19. The method of claim 18, wherein the exposed first pattern features comprise a first exposed feature having a first width adjoining the exposed continuous first region, a second exposed feature having a second width adjoining the first exposed feature, and a third exposed feature having a third width adjoining the second exposed feature, wherein the exposed continuous first region and each of the first, second, and third exposed features comprise a shared edge, the third width is less than the second width, and the second width is less than the first width.

20. The method of claim 18, wherein the exposed first pattern features comprise a first exposed feature having a first width adjoining the exposed continuous first region and a second exposed feature having a second width adjoining the first exposed feature but not the exposed continuous first region, wherein the second width is greater than the first width and the exposed continuous first region, first exposed feature, and second exposed feature are aligned along a shared center axis of the exposed continuous first region, first exposed feature, and second exposed feature.

21. The method of claim 18, wherein the exposed first pattern features comprise a grid of first exposed features within the first region.

22. The method of claim 18, wherein a shared boundary between the exposed first pattern features and the unexposed first pattern features has a first boundary length that is not less than 1.75 times the constant first width.

23. The method of claim 18, further comprising:
patterning a dielectric layer using the resultant trench pattern to form a trench in the dielectric layer; and
forming a metal line in the trench.
